(19) United States
(12) Patent Application Publication
(10) Pub. No.: US 2017/0142830 A1
(43) Pub. Date: May 18, 2017

(54) Reinforcement Structures With a Thermal Conductivity-Increasing Coating in the Resin Matrix, and Electrical Conductor Structure Which is Separate From the Coating

(71) Applicant: AT & S Austria Technologie & Systemtechnik Aktiengesellschaft, Leoben (AT)

(72) Inventors: Elisabeth Kreutzwiesner, Graz (AT); Gernot Schulz, Graz (AT)

(73) Assignee: AT & S Austria Technologie & Systemtechnik Aktiengesellschaft, Leoben (AT)

(21) Appl. No.: 15/127,725

(22) PCT Filed: Mar. 20, 2015
(86) PCT No.: PCT/EP2015/055979

§ 371 Date: Sep. 20, 2016

(30) Foreign Application Priority Data
Mar. 21, 2014 (DE) 10 2014 103 954.8

(51) Int. Cl. H05K 1/03; H05K 1/09; H05K 1/18; H05K 3/28; H01B 3/48; H05K 1/02

(52) U.S. Cl. CPC H05K 1/0366; H01B 3/48; H05K 1/0209; H05K 1/185; H05K 3/28; H05K 1/09; H05K 2201/029

(57) ABSTRACT

Electronic device comprising an at least partially electrically insulating carrier structure, which comprises a resin matrix and reinforcement structures in the resin matrix, wherein the reinforcement structures are provided at least partially with a thermal conductivity increasing coating, and an electrically conducting structure at and/or in the carrier structure, wherein at least in an interconnecting section between the carrier structure and the electrically conducting structure, the carrier structure is free from reinforcement structures provided with the coating, such that the electrically conducting structure and the coating are arranged non-contactingly relative to each other.

### CROSS-REFERENCE TO RELATED APPLICATIONS

This application is a U.S. national phase patent application of PCT/EP2015/055979 and claims the benefit of the filing date of German Patent Application No. DE 10 2014 103 954.8, filed on Mar. 21, 2014, the disclosures of which are hereby incorporated herein by reference in their entirety.

### TECHNICAL FIELD

The invention relates to an electronic device and a method for manufacturing an electronic device.

Technological Background

In the manufacturing of electronic devices, there are components having a different generation of heat (for example power electronics components) as well as components having a different thermal sensitivity (for example electrolytic capacitors, which have a shorter lifetime at increased temperature). Generally, it can be stated that the lifetime can be strongly extended by lowering the operation temperature of the components by 10° C.

Prints and printed circuit boards comprise an electrically insulating carrier material, on which at least one copper layer is deposited. At present, the layer thicknesses of these carrier materials amount to, for example, at least 35 μm (wherein the tendency goes to further down-sized structures) and comprise, for example, glass fibre mats, which are impregnated in epoxy resin (FR4, flame resistant).

The fact that by means of an improvement of the thermal conductivity also the lifetime of an electronic device can be extended, can be provided for already during the layout of a printed circuit board. However, it has turned out that due to the increasing miniaturization, the thermal conduction through the print guides large amounts of heat to sensitive components.

WO 2006/002013 A1 and US 2005/0277350 A1 disclose a structure, by means of which the thermal conductivity of substances is to be facilitated by surface coating of the substances with materials having a high thermal conductivity. The substances can be surface-coated, if they comprise individual fibres, bundles consisting of fibres, mats of fibres or combinations thereof. A special type of such a fibre matrix employs glass. Some fabrics (or textures) may be a combination of more than one type of substance or may comprise different materials in alternating layers. Diamond like (or adamantine) coatings (DLC) as well as metal oxides, nitrides, carbides and mixed stoichiometric and non-stoichiometric combinations thereof, which can be added to a base matrix, may be utilized as thermally highly conducting coatings.

US 2014/0060898 A1 discloses a multi-layered conductor board (or printed circuit board) comprising a substrate layer, electrically conducting layers and an electronic component that is mounted on the conductor plate. The substrate layer comprises a matrix material and reinforcing fibres as well as thermally conductive particles. The conductor board thus has improved thermal properties.

### SUMMARY

There may be a need to provide an electronic device, which is operable also under robust operating conditions, and which ensures an efficient dissipation (or carry-off) of heat in operation.

This need is satisfied_by the objects having the features according to the independent claims. Further embodiment examples are shown in the dependent claims.

According to an example embodiment of the present invention, there is provided an electronic device, which comprises an at least partially electrically insulating carrier structure, which comprises a resin matrix and reinforcement structures in the resin matrix, wherein the reinforcement structures are provided with a coating that increases the thermal conductivity (herein called: “thermal conductivity increasing coating”) (for example at least 1 W/mK, particularly at least 20 W/mK, further particularly at least 50 W/mK, still further particularly at least 100 W/mK, for example approximately 200 W/mK) particularly with a thermally highly conductive coating, and an electrically conducting structure at and/or in the carrier structure, wherein at least in an interconnecting section between the carrier structure and the electrically conducting structure, the carrier structure is free from reinforcement structures that are provided with the coating, such that the electrically conducting structure and the coating are arranged non-contactingly [relative] to each other (i.e. do not contact each other directly).

In the context of this application, the term “thermal conductivity increasing coating” (or “coating that increases the thermal conductivity”) is understood to refer to a coating of the reinforcement structures, which coating is in particular formed from such a material, which coating material has an increased value of the thermal conductivity as compared to a material of the reinforcement structures. In this way, the coating increases the thermal conductivity of the coated reinforcement structures in comparison to uncoated reinforcement structures. In particular, the coating may also have a value of the thermal conductivity, which is higher than the value of the thermal conductivity of the resin matrix. For example, conventional prepreg material as an example for an arrangement consisting of a resin matrix having embedded reinforcement structures made of glass may have an average or resulting thermal conductivity of about 0.3 W/mK, such that by means of a coating according to the invention with a material comprising a thermal conductivity of, for example, at least 1 W/mK, there may be achieved an improvement of the thermal conductivity both in comparison to the reinforcement structures alone and also in comparison to a combination consisting of the reinforcement structures and the resin matrix.

According to a further example embodiment of the present invention, there is provided a method for manufacturing an electronic device, wherein in the method, an at least partially electrically insulating carrier structure is formed, which comprises a resin matrix and reinforcement structures in the resin matrix, wherein the reinforcement structures are at least partially provided with a thermal conductivity increasing coating, and an electrically conductive structure is formed at and/or in the carrier structure, wherein at least in an interconnecting section between the carrier structure and the electrically conducting structure, the carrier structure is kept free from reinforcement structures provided with the coating, such that the electrically conducting structure and the coating are arranged non-contactingly [relative] to each other.

According to an example embodiment of the present invention, there is established an electronic device, in which an at least section-wise or completely dielectric carrier structure made of reinforcement structures is formed, which [reinforcement structures] are jacketed with a thermal conductivity increasing coating. The reinforcement structures are embedded in a resin matrix. These components are configured as an electrically insulating core, on and/or in which electrically conducting contacting structures are attached to. The dielectric carrier structure provides a reliable electrical insulation in operation of the electronic device, whereas the current conducting contacting structures are formed for conducting electrical signals along defined paths through the electronic device. The reinforcement structures, on one hand, serve as a mechanical stabilization of the electrically insulating carrier structure and therefore the electronic device as a whole, and, on the other hand, provide, by virtue of their thermal conductivity increasing jacket, for an effective and by the design of the coated reinforcement structures precisely adjustable dissipation (or carry-off) of waste heat incurred during the operation of the electronic device. Though, the palette of coatings of the reinforcement structures, which are at the same time electrically insulating and on the other hand thermal conductivity increasing, is strongly restricted due to physical limiting factors (or framework conditions) (since in many materials, the processes of the thermal conductivity and of the electrical conductivity are similar). Now, coating materials that are suitable for the electrical insulation as well as for the high thermal conductivity have, as has been recognized by the present inventors, poor adhesive properties on desirable electrically highly conductive structures (such as for example copper). Thus, in the case of a direct contact between the coating of the reinforcement structures and the electrically conducting structure due to the utmost moderate adhesive properties, there may come about an undesired delamination of the electrically conductive structure from the coating and, accordingly, a damage of the electronic device. In order to improve the reliability and the operational stability of the electronic device without degradation of the mechanical stability and thermal dissipation capability, the electrically conductive structure according to the invention is thus conceived to be contact-free from the coating. By making impossible a direct touch contact between the electrically conductive structure and the thermal conductivity increasing coating, there is provided an electronic device, which is applicable even under robust operating conditions and can be manufactured with little effort, and which can ensure an efficient dissipation (or carry-off) of heat.

### Exemplary Embodiments

Additional example embodiments of the device and the method are described in the following.

According to an example embodiment, the reinforcement structures may comprise reinforcement fibres. In this context, a fibre is understood to be an, in particular elongated structure, which has in particular an aspect ratio (i.e. a ratio of length to diameter) of at least three, particularly at least five, further particularly at least ten. Such reinforcement fibres, which may be provided or jacketed with a thermal conductivity increasing coating may serve demonstratively as thermally well conducting conduits in the electronic device, by which a controlled dissipation of heat along the fibre may be possible.

According to an example embodiment, the reinforcement fibres may be cross-linked with each other, particularly with formation of cross-linking planes (or cross-linking layers), which may be further particularly oriented perpendicular to a thickness direction of the device or stacked one over the other perpendicularly to the thickness direction of the device. By the forming of fabrics (or webbings), rovings or cross-interlockings from the reinforcement fibres in an essentially planar manner, mechanically robust reinforcement webs may be formed, which, at the same time, may convey stability and may enable an efficient dissipation of heat to a board-type carrier structure. According to an example embodiment, the reinforcement fibres in the resin matrix may be oriented anisotropically, such that the heat conduction in the electrically insulating carrier structure is effected anisotropically. An anisotropical orientation of the reinforcement fibres in the resin matrix may thus lead to an anisotropic dissipation of ohmic losses incurred in the operation of the electronic device. By the type and the degree of the anisotropy, also the heat dissipation along predeterminable pathways with respective presettable partial intensities may be precisely adjusted and thus a deterministic heat management may be implemented.

According to an example embodiment, a first portion of the reinforcement fibres may extend along a first preferred direction, and a second portion of the reinforcement fibres may extend along another, second preferred direction, wherein the first preferred direction and the second preferred direction are arranged angularly (particularly acute-angled or right-angled) relative to each other. By the resulting rovings or fabrics with touching points or crossing points, a mechanically stable configuration may be obtained, which, at the same time, may have good thermal dissipation properties. Different properties of the reinforcement fibres along the first preferred direction in comparison to those along the second preferred direction may allow the presetting (or predetermination) of different heat dissipation properties in different directions.

According to an example embodiment, the first portion of the reinforcement fibres may have a ratio of a coating volume (that is the proper volume of the coating of the reinforcement structures of the first part) to a taken volume of the carrier structure, which may differ from a ratio of the coating volume (that is the proper volume of the coating of the reinforcement structures of the second part) to the taken volume of the carrier structure of the second part of the reinforcement fibres. Since the respective coating volume may dominate essentially the thermal conductivity of the jacketed reinforcement structures (the reinforcement structures may be formed of materials, such as glass, which may be thermally poorly or moderately conductive), also the pro rata (or partial) heat dissipation in the associated extension directions may be adjusted by the presetting (or specification) of different coating volumes for the two portions of the reinforcement fibres. Different coating volumes may be predetermined (or preset) by a different number and/or thickness of reinforcement structures, different coating thicknesses, etc., for the different portions of accordingly oriented reinforcement fibres.

According to an example embodiment, the reinforcement structures may comprise reinforcement grains, particularly reinforcement balls (or spheres). Thus, at least a portion of the reinforcement structures may be formed as bodies that are essentially equally sized (or dimensioned) in the different extension directions. Such bodies may be balls, granulates, cuboids, cubes, cylinders, cones, etc. By using such bodies, essentially isotropical thermal conductivity properties may be adjusted advantageously. By a selection of a thickness and/or a volume fraction in the carrier structure and/or material of such reinforcement grains, the absolute value of the thermal conductivity in the carrier structure (homogeneously or spatially inhomogeneously) may be adjusted precisely, particularly also in different spatial regions of the electrically insulating carrier structure in a different manner. Furthermore, when conceiving such reinforcement grains, it may be unnecessary to form textures from fibres, which simplifies the manufacturing process.

According to an example embodiment, the reinforcement structures may comprise hollow bodies, particularly hollow fibres and/or hollow balls (or spheres). The embedding of heat conductivity increasing, coated or jacketed hollow bodies in the resin matrix may allow providing a light-weight electronic device having, which nevertheless has good heat dissipation properties.

According to an example embodiment, the reinforcement structures may comprise glass or consist thereof. In particular, the reinforcement structures may be glass fibres and/or glass balls. Thereby, the manufacturability of the electronic device may be brought in line (or harmonized) with the processes and materials that are advantageous for the formation of printed circuit boards (PCBs).

According to an example embodiment, the device may comprise at least one (advantageously electrically insulating) separation structure, which may be arranged as a spatial separation or decoupling between the coated reinforcement structures and the electrically conducting structure. Such separation coatings may for example be pure resin layers or prepreg layers (with coating-free glass fibres), which may be grouted with the electrically insulating carrier structure and the electrically conductive structure (or a preform thereof), in order to form a compression bond as the electronic device. Such a separation layer, which may be free from the coating material of the reinforcement structures, may demonstratively serve as a spacer (or distance piece) between the electrically conducting structure and the coating and may thus reliably inhibit their direct contact. One or more of such separation layers may thus further reduce the risk, that components of the electrically conductive structure detach (or peel off) from the rest of the electronic device.

According to an example embodiment, the coating may be optically impermeable. In particular, if the reinforcement bodies (which are often manufactured from glass) themselves are optically transparent, they may interact with photons that are undesirably present in the interior of the carrier structure. The latter may then couple in a parasitic manner into the reinforcement fibres that function demonstratively as light guides and accordingly may undesirably come in interaction with, for example, components that may be embedded in the electronic device (for example an optical sensor or an electronic filter). An undesired propagation of light through the reinforcement structures may be suppressed by the opaque coating of the reinforcement structures.

According to an example embodiment, the coating may have a thickness in the range of between approximately 300 nm and approximately 10 μm, particularly in a range between approximately 750 nm and approximately 10 μm. For thicknesses of less than 300 nm, the optical intransparency may no longer be sufficiently high and, moreover, the thermal conductivity may no longer be good enough for many modern electronic applications. However, if a thickness of 10 μm is exceeded, then the coating may become prone to a detaching (or delamination) from the reinforcement structures, which would deteriorate the reliability of the electronic device. In addition, experiments have revealed, that the coating may be impermeable for electromagnetic radiation with wavelengths even in the range of 250 nm to 3500 nm, if the layer has a thickness of at least 750 nm. Thus, a coupling-in of light may be suppressed advantageously not only in the visible range into the reinforcement structures, but also in ranges of wavelengths that are neighbouring on both sides in the infrared and ultraviolet range.

According to an example embodiment, the coating may be a carbonaceous (or carbon-containing) coating comprising a mixture of sp² and spa hybridized carbon (preferably a hydrogenous (or hydrogen-containing) and/or amorphous such coating). A possible proportion of hydrogen in the coating material should not become too high, because the thermal conductivity is reduced at very high proportions of hydrogen. On the other hand side, the optional proportion of hydrogen in the coating material also should not become too low, because otherwise the coating material may become brittle and may generate a high mechanical tension in the coating. In the presence of an external mechanical load, this may lead to a scribing of the coating. The proportion of hydrogen in a carbonaceous coating comprising a mixture of sp² and sp³ hybridized carbon should advantageously be between 10 percentage of weight and 30 percentage of weight.

According to an example embodiment, the proportion of sp² hybridized carbon may be in a range between approximately 30 and approximately 65 percentage of weight, particularly between approximately 40 and approximately 60 percentage of weight, of the coating. The proportion of sp³ hybridized carbon may advantageously be in a range between approximately 20 and approximately 70 percentage of weight, particularly between approximately 25 and approximately 40 percentage of weight, of the coating.

According to an example embodiment, the reinforcement structures provided with the coating, i.e. the combination of coating and reinforcement structure, may have a thermal conductivity in a range between about 1 W/mK and about 45 W/mK, particularly in a range between about 3 W/mK and about 30 W/mK. Significantly higher values of the thermal conductivity may lead to unstable mechanical conditions in the carrier structure and/or may make necessary the use of exotic materials, which may be undesirable for the electronic device in many cases. Significantly lower values of the thermal conductivity may limit the heat dissipation properties in an undesirable manner. In comparison with conventional prepreg material or FR4 material, such as those used for the manufacturing of printed circuit boards, the mentioned ranges may enable a significant improvement of the heat dissipation properties.

According to an example embodiment, the reinforcement structures that are provided with the coating may be jacketed with resin (or resin-covered) and the electrically conductive structure may be conceived on and/or above the resin jacket, in order to thus separate the electrically conductive structure and the coating from each other non-contactingly. A sufficiently thick and reliable resin jacket of the reinforcement structures that are provided with the coating may also avoid an undesired touch contact between the metallic, particularly formed from copper, electrically conductive structure and the coating material, particularly DLC (Diamond Like Carbon). Thereby, the jacketing with resin of the reinforcement structures that are jacketed with the coating may be carried out as a separate process prior to the impregnation with resin of the resulting semifinished product or during this impregnation.

According to an example embodiment, the electrically insulating carrier structure may be formed from prepreg material. Prepreg (short form for pre-impregnated fibres) refers to pre-impregnated fibres. Prepreg refers particularly to a semifinished product made of fibres and an unhardened thermosetting plastic matrix. The fibres may be available as a purely uni-directional layer or as a texture (or webbing) or a roving.

According to an example embodiment, the carrier structure may be a resinous (or resin-containing) board, particularly a resin-glass fibre-board. The material used for the resin matrix may, for example, comprise epoxy resin or may consist thereof.

According to an example embodiment, the electrically insulating carrier structure may be formed by providing the reinforcement structures individually with the heat conductivity increasing coating, by cross-linking the coated reinforcement structures with each other (particularly by forming a texture (or webbing) or a roving), and by impregnating the jointly cross-linked, coated reinforcement structures in liquid resin. According to this embodiment, the coating may be performed prior to the cross-linking. After the impregnation with resin, a hardening of the composite may be effected.

According to an alternative example embodiment, the electrically insulating carrier structure may be formed by cross-linking the reinforcement structures with each other (particularly by forming a coating (or webbing) or a roving), by jointly providing the cross-linked reinforcement structures with the heat conductivity increasing coating, and by impregnating the jointly cross-linked, coated reinforcement structures in resin. According to this embodiment, the coating may be performed after the cross-linking. After the impregnation with resin, again, a hardening of the composite may be effected.

According to an example embodiment, the reinforcement structures may be provided with the coating by means of sputtering (also called cathode evaporation or physical vapour deposition (PVD), wherein a target on a surface is bombarded with ions, in order to dissolve particles away therefrom) and/or plasma enhanced chemical vapour deposition (PECVD, wherein the coating deposits from a gas phase or a plasma phase). For example, in the formation of DLC coatings, a coating with a low proportion of hydrogen and thus a good thermal conductivity may be obtained by means of coating by PVD, wherein the layer thickness should then, for reasons of mechanical integrity, not be selected too great. In contrast, a coating having a higher proportion of hydrogen may be manufactured by means of coating by PECVD, wherein the coating may exhibit a particularly good mechanical tensile strength, but may have worse heat dissipation properties than in the case of PVD.

According to an example embodiment, a first portion of the reinforcement structures may be aligned along a first extension direction, and a second portion of the reinforcement structures may be aligned along a second extension direction, wherein a distance between neighbouring reinforcement structures of the first portion may be conceived [to be] different from a distance between neighbouring reinforcement structures of the second portion. By the adjustment of a greater (or smaller) distance, a lower (or higher) density of reinforcement structures and thus a reduced (or increased) heat dissipation may be adjusted.

According to an example embodiment, the electrically conducting structure may comprise copper or may consist thereof. Alternatively or in addition, other metals may be used, for example aluminium or nickel.

According to an example embodiment, the device may comprise an electronic component, which is embedded in the carrier structure and is coupled electrically conductingly with the electrically conductive structure. The at least one electronic component may comprise an active electronic component and/or a passive electronic component. For example, it may be possible to implement in the electrically insulating carrier structure, as an electronic component a filter (for example a frequency filter, particularly a high pass filter, a low pass filter or a bandpass filter), a voltage converter (for example a DC/DC converter or an AC/DC converter), a semiconductor chip (i.e. an IC), a storage module (for example a DRAM), a capacitor, an ohmic resistance, an inductor, a sensor (for example a gas sensor, a chemical sensor, an optical sensor, a capacitive sensor, a fingerprint sensor, etc.) and/or a high frequency component.

According to an example embodiment, the carrier structure may be formed of plural layers arranged one over the other, wherein the device may have furthermore at least a further electrically conductive structure between the layers. The electronic device may thus be formed as a multi-layer structure, in which electrical signals are transmitted between different layers in a horizontal and/or a vertical direction. Thereby, also complex circuitry-wise functions may be implemented using the device according to the invention.

According to an example embodiment, the device may be formed as printed circuit board. A printed circuit board (circuit board, circuit card or printed circuitry; PCB, Printed Circuit Board) may be referred to as a carrier for electronic components. A circuit board may serve for the mechanical attachment and electrical connection. Circuit boards may comprise electrically insulating material as a carrier structure with conducting connections adhering thereto, i.e. conductor paths and contact structures. Fibre-enhanced plastic may be possible as an insulating material. The conductor paths may be etched from a thin layer of copper.

### BRIEF DESCRIPTION OF THE DRAWINGS

In the following, exemplary embodiments of the present invention are described in detail with reference to the following figures.

FIG. 1 shows a cross-sectional view of an electronic device according to an exemplary embodiment example of the invention.

FIG. 2 shows a plan view of reinforcement fibres of an electronic device, which fibres are cross-linked with each other to a texture, according to an exemplary embodiment example of the invention.

FIG. 3 shows a phase diagram, which illustrates the contributions of sp² hybridized carbon, spa hybridized carbon and hydrogen of a coating material for the coating of reinforcement structures in a resin matrix, according to an exemplary embodiment of the invention.

FIG. 4 shows a cross-sectional view of an electronic device according to another exemplary embodiment example of the invention.

FIG. 5 shows reinforcement fibres that are aligned along a first extension direction and reinforcement fibres that are aligned along a second extension direction that is oriented angularly thereto, with anisotropic heat conductivity properties of an electronic device according to an exemplary embodiment example of the invention.

FIG. 6 shows a plan view of a mat made from reinforcement fibres that are aligned along a first extension direction and reinforcement fibres that are aligned along a second extension direction that is oriented angularly thereto, of an electronic device according to an exemplary embodiment example of the invention, wherein a coating with heat conductivity increasing coating material has been performed only after the formation of the mat.

### DETAILED DESCRIPTION OF ILLUSTRATED EMBODIMENTS

Same or similar components in different figures are provided with the same reference signs.

Before example embodiments of the invention are described with reference to the figures, some general aspects of the invention shall be explained yet:

Example embodiment s are based on the idea to coat (particularly glass-) fibres, from which prepreg (FR4) can be manufactured, with a heat conducting coating (for example made from DLC). Thereby, both the heat distribution and also the heat dissipation in an electronic device can be adjusted.

According to a first aspect of the invention, an adjustment of the anisotropy of the heat conduction in an electronic device can advantageously be obtained by means of a highly thermally conductive coating. According to the invention, this can be solved by providing a print material, which has different thermal conductivity values in the x- and y-direction (i.e. in two directions that are orthogonal to the z- or thickness-direction of the print). This can be achieved by coating glass fibres, for example, with a specialized form of carbon (particularly, a hydrogenous amorphous carbon layer made of a mixture of sp² and spa hybridized carbon atoms, alternatively or additionally nitrides, oxides, such as, for example, aluminium nitride or aluminium oxide, copper oxide, etc.). Thereby, this thermally conducting layer may be deposited on the glass fibres by means of PVD or PACVD in layer thicknesses of, for example, at maximum 10 μm. Astonishingly, it was found, that different yarn densities can be obtained in the x- and y-direction by according weaving and fabrication techniques, which leads to a different heat conductivity and heat distribution in the x- and in the y-direction. This anisotropic heat conduction may be conserved with the embedding in the finished print. Heat conductivities/heat distributions of the utilized texture of more than 0.8 W/mK up to 50 W/mK are achieved by this layer. Such devices can be used as basic materials, which may be applied for products, in which heat is generated during operation and is to be dissipated and/or to be forced apart (or spread). From the manufacturing standpoint it may be simple to produce an anisotropic heat conduction by a mechanical distorting or straining of prepregs (asymmetry of the texture in the x- and y-direction).

According to a second aspect of the invention, coated fibres that are impermeable for light can be applied. Prints can be formed from electrically isolating carrier materials, on which at least one copper layer may be deposited. These carrier materials may often be formed from transparent mats of glass fibres, which may be impregnated in epoxy resin (FR4, FR refers to flame resistant), for example with layer thicknesses of at least 35 μm. The increasing miniaturization of electronics and of chip technology has led to the power consumption of electronic components having become smaller. At present, operational amplifiers having input currents in the range of Femtoamperes are available, and values significantly below this may be typical in integrated circuits. Beside the requirements for very high isolation resistances, recently also the set of problems of the photo effect (photoelectric effect: By the impinging of a photon, an electron is released) may be posed. This set of problems may appear above all for laid open chips and visually accessible components. Especially, in the embedding of components in printed circuit boards, the relatively good light transmission (or transparancy) of FR4 may become a big problem: The glass fibres (of the FR4 materials) may function like optical waveguides and thus may guide the photons, which therefore may lead to disturbances at the signal level. According to an embodiment example of the invention, this problem can be solved by coating the fibres with a material that is impermeable for light (for example amorphous carbon). By forming such layers, the transparency of the FR4 material may be lowered and thus also the conduction of the photons in the glass fibres may be prevented or strongly suppressed. Astonishingly, also an improved heat dissipation and heat distribution in the FR4 material can thereby be achieved as a side effect.

According to a third aspect of the invention, balls (or spheres) and hollow balls, which are made of glass and have a heat dissipating coating, can be applied. This may lead to a simple manufacturing method and (when using hollow bodies as the reinforcement structures) to a light-weight circuit board.

In particular and according to an example embodiment of the invention, a material for circuit boards, a print material or a substrate material can be provided, which may be formed of a resin component and a reinforcement component. The reinforcement components may be provided with a coating, which may be a hydrogenous amorphous carbon layer consisting of a mixture of sp² and sp³ hybridized carbon atoms. The heat conduction/heat distribution of the applied texture can lie above 0.8 W/mK and below 50 W/mK. The heat conductivity in the x- and the y-direction may be unequal from one another (anisotropic heat distribution). For example, the difference of heat conductivity x:y may be larger than 1.1:1, preferably larger than 1.5:1, further preferably larger than 2:1. The proportion of sp² hybridized carbon atoms can amount to 30 to 65 percent per weight and the proportion of sp³ hybridized carbon atoms can amount to 20 to 70 percent by weight. In particular, the proportion of sp² hybridized carbon atoms can amount 40 to 60 percent by weight, and the proportion of sp³ hybridized carbon atoms can amount 25 to 40 percent by weight. The coating can be impermeable for light, whereby electromagnetic radiation may not pass (may not transmit). For example, the impermeability for light can be higher than for window glass by at least a factor of ten.

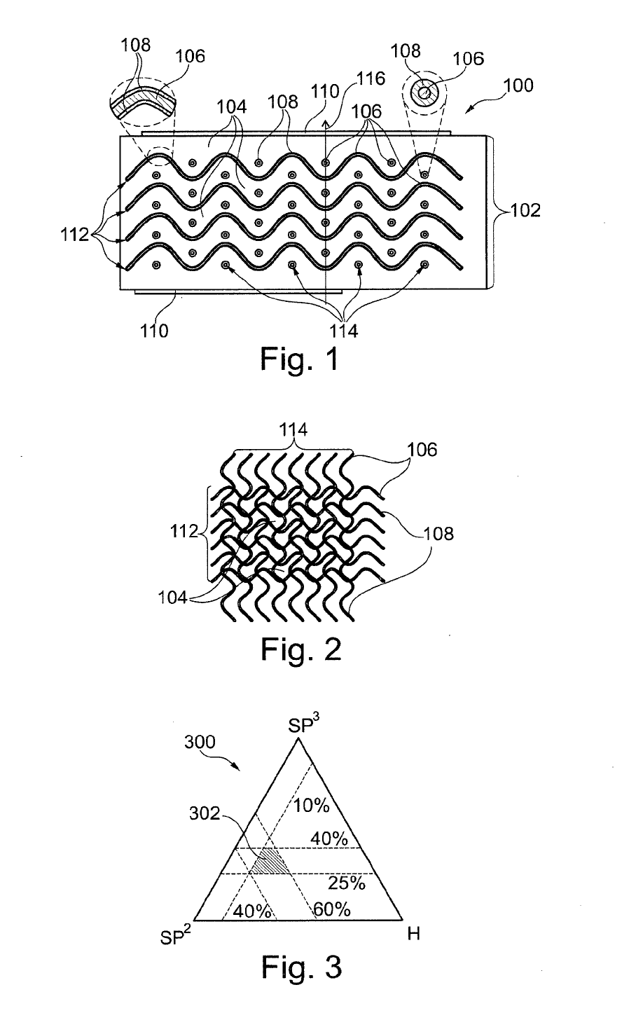

FIG. 1 shows a cross-sectional view of an electronic device 100 that is formed as a printed circuit board, according to an exemplary embodiment of the invention.

The electronic device 100 shown in FIG. 1 has a plate-shapedly formed, electrically isolating carrier structure 102, which comprises a resin matrix 104 formed from epoxy resin, and reinforcing structures 106 formed as glass fibres, which are embedded in the resin matrix 104. The reinforcement structures 106 may be jacketed with a thermally highly conductive coating 108 made of DLC (Diamond Like Carbon).

Conductor pathways made from copper may be formed on both opposite main surfaces of the carrier structure 102 as an electrically conductive structure 110.

As can be seen in FIG. 1, in a respective interconnection section between the carrier structure 102 and the respective electrically conductive structure 110, the carrier structure 102 is free from reinforcement structures 106 that are provided with the coating 108. Furthermore, the reinforcement structures 106 that are provided with the coating 108 may be jacketed with resin and the electrically conductive structure 110 may be provided on the resin jacket, in order to also thereby separate the electrically conducting structure 110 from the coating 108 free of contact (or non-contactingly). Accordingly, the electrically conductive structure 110 and the coating 108 may be non-contacting to one another, i.e. without straight or direct physical contact to each other, localized or positioned at the electronic device 100. An undesired release of the electrically conductive structure 110 from the coating 108, which would adhere to the electrically conductive structure 110 only poorly, may thereby be avoided.

The reinforcing structures 106, which may be wave-like (or undulating) in the shown embodiment example, may be cross-linked with one another with the formation of a respective roving, such that cross-linking layers or cross-linking planes may be formed, which may be oriented perpendicular to a thickness direction 116 of the board-like device 100. The reinforcement structures 106 may be aligned anisotropically in the resin matrix 104, such that heat conduction in the electrically isolating carrier structure 106 may be effected anisotropically. Stated more precisely, a first portion 112 of the reinforcement fibres 106 may extend along a first preferred direction (a horizontal direction according to FIG. 1), whereas a second portion 114 of the reinforcement fibres 106 may extend along a second preferred direction (perpendicular to the paper plane according to FIG. 1).

The coating 108 made of DLC may be impermeable for electromagnetic radiation in the visible range, i.e. for optical light. For this purpose, the coating 108 may have a sufficiently high thickness of, for example, 1 μm. A coating 108 of such thickness also may lead to an efficient thermal dissipation of heat, which may be incurred in the operation of the electronic device 100 due to the propagating electronic signals, etc. The reinforcement structures 106 provided with the coating 108 may have jointly on average a thermal conductivity of, for example, about 10 W/mK.

Since the coating 108 may be in contact only with the material of the reinforcement structures 106 and the resin material of the resin matrix 104, but not with the copper material of the electrically conductive structure 110, a delamination of the copper from the electronic device 100 may be avoided, because a direct contact of the copper with the DLC material, which may be incompatible therewith, may be made impossible. Due to the alignment of the first portion 112 and the second portion 114 of the reinforcement structures 106, which may be completely jacketed with the coating 108, along mutually orthogonal directions, also preferred directions for the dissipation of thermal energy in the horizontal direction according to FIG. 1 and in a direction perpendicular to the paper plane according to FIG. 1 may be specified (or predetermined), such that heat dissipation properties, which may depend on the direction and may be precisely definable, can be adjusted. By selecting a sufficiently thick coating 108, optically intransparent properties of the coated reinforcement structures 106 can be achieved, such that an undesired coupling-in of parasitically generated photons in the glass fibre reinforcement structures 106, that otherwise may act factually as light guides, may be avoided, which otherwise could disturb the electrical quality of the electronic device 100.

FIG. 2 shows a plan view of reinforcement structures 106 (in the form of fibres), which are cross-linked with each other as a texture (or webbing), of an electronic device 100 according to an exemplary embodiment example of the invention. According to FIG. 2, the reinforcement structures 106 may form a mechanically robust mat with good stability and heat dissipation properties.

FIG. 3 shows a phase diagram 300, which shows the contributions of sp² hybridized carbon, sp³ hybridized carbon and hydrogen of a coating material for the coating of reinforcement structures 106 in a resin matrix 104, according to an exemplary embodiment example of the invention.

According to the phase diagram 300, the coating 108 may be a hydrogenous (or hydrogen-containing) (H) amorphous carbon coating comprising a mixture of sp² and sp³ hybridized carbon. Preferably, the proportion of sp² hybridized carbon may be in a range between 40 and 60 percentage by weight of the coating 108, the proportion of sp³ hybridized carbon may be in a range between 25 and 40 percentage by weight of the coating 108, and the proportion of hydrogen may be above 10% (but preferably not above 40%). If sputtering/PVD is employed for the manufacture of the coating 108, the proportion of sp² hybridized carbon may be high. In contrast, if PECVD is employed for the manufacture of the coating, a higher proportion of hydrogen may be obtained. A high thermal conductivity of the coating 108 can be achieved using a high proportion of sp² and sp³ hybridized carbon. A mechanically stable coating 108 having a relatively high layer thickness may be manufacturable with a high proportion of hydrogen. The mechanical and thermal properties of the coating 108 can be adjusted precisely by the selection of the manufacturing method (for example, also the adjustment of the precise process parameters or, if applicable, combinations of the two mentioned manufacturing methods). A composition, which may be particularly advantageous in this respect, is represented in FIG. 3 as an area, which is referenced with the reference numeral 302.

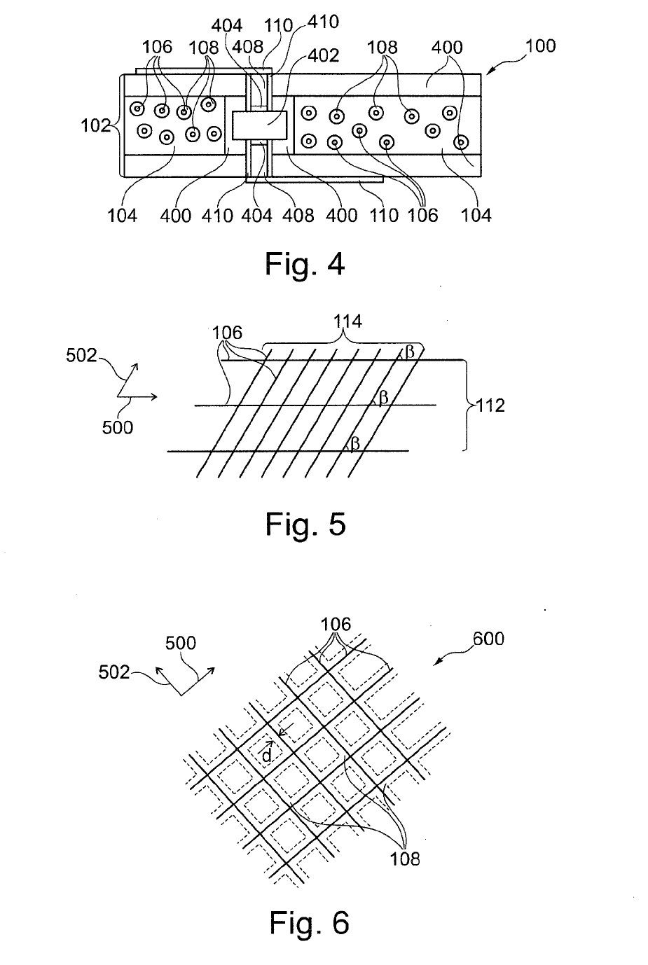

FIG. 4 shows a cross-sectional view of an electronic device 100 according to another exemplary embodiment example of the invention.

In contrast to the electronic device 100 shown in FIG. 1, in the electronic device 100 according to FIG. 4, a plurality of separation structures 400 (here formed as separation layers) which may be formed from resin, are conceived, which may be arranged as spacers (or distance pieces) for a spatial separation between the coated reinforcement structures 106 and the electrically conducting structure 110.

According to FIG. 4, the reinforcement structures 106 may be formed as ball-shaped reinforcement grains, which can be realized selectively as massive bodies (if, for example, a particularly high mechanical stability is desired) or as hollow bodies (if, for example, a particularly low weight is desired).

In the electronic device 100, stated more precisely in the carrier structure 102 thereof, an electronic component 402 (for example a semiconductor storage) may be embedded, which may comprise an upper side and a lower side electrically conducting pad 404. The pads 404 may be coupled electrically conductingly with the electrically conductive structure 110 by means of a vertical via 408. In order to suppress (or prevent) a direct contact between the pads 404 made for example from copper or the vias 408 formed, for example, from copper and the jacketing 108 of the reinforcement structures 106, the vias 408 and the pads 404 may be surrounded on the side and/or circumferentially by an electrically conducting spacer structure 410.

FIG. 5 shows reinforcement structures 106, which are aligned along a first extension direction 500, and reinforcement structures 106, which are aligned along a second extension direction 502 that is oriented angularly thereto (see the acute angle β), having anisotropic heat conductivity properties of an electronic device 100 according to an exemplary embodiment example of the invention.

The first portion 112 of the reinforcement fibres 106 may have a ratio of a coating volume to the taken volume of the carrier structure 102, which may be smaller than a ratio of the coating volume to the taken volume of the carrier structure of the second portion 114 of the reinforcement fibres 106. The spatial density of the reinforcement fibres 106 of the first portion 112 may be lower than the spatial density of the reinforcement fibres 106 of the second portion 114. Thus, also the pro rata (or partial) coating volume of the second portion 114 in relation to the total carrier structure 102 may also be larger than in the case of the first portion 112. According to FIG. 5, the heat conduction may thus be effected anisotropically, i.e. with a higher efficiency along the second extension direction 502 in comparison to the first extension direction 500.

FIG. 6 shows a mat 600 of reinforcement structures 106, which are aligned along a first extension direction 500, and reinforcement structures 106, which are aligned along a second extension direction 502 that is oriented angularly thereto, of an electronic device 100 according to an exemplary embodiment example of the invention, wherein a coating 108 having a heat conductivity increasing coating material is produced only after the formation of the mat 600. Due to this manufacturing method, the reinforcement structures that intersect (or cross) each other may be mechanically connected with each other by the coating 108. The mat 600 can then be impregnated in resin, which can be hardened subsequently. The produced composite can then be compressed with other components (for example with copper layers), if needed, and can be re-treated if applicable (for example, structured). If a thickness d of the coating 108 amounts to between 750 nm and 10 μm, both an advantageous intransparency of the coating 108 for electromagnetic radiation in a broad wavelength range from infrared via the visible to the ultraviolet range may be achievable, and a good adhesion of the coating 108 to the reinforcement structures 106 may be achievable.

Supplementary, it is to be noted that “comprising” or “having” does not exclude other elements or steps, and that “a” or “an” does not exclude a plurality. It is further to be noted that features or steps, which have been described with reference to one of the embodiment examples above, can be applied also in combination with other features or steps of other embodiment examples described above. Reference numerals in the claims are not to be considered as limitations.

1. Electronic device comprising:
an at least partially electrically insulating carrier structure, which comprises a resin matrix and reinforcement structures in the resin matrix, wherein the reinforcement structures are at least partially provided with a thermal conductivity increasing coating;
an electrically conducting structure at and/or in the carrier structure;
wherein at least in an interconnecting section between the carrier structure and the electrically conducting structure, the carrier structure is free from reinforcement structures provided with the coating, such that the electrically conducting structure and the coating are arranged non-contactingly relative to each other.

2. Device according to claim 1, wherein the reinforcement structures comprise reinforcement fibres.

3. Device according to claim 2, wherein the reinforcement fibres are cross-linked with each other, with formation of cross-linking layers, which are oriented perpendicular to a thickness direction of the device.

4. Device according to claim 2, wherein the reinforcement fibres in the resin matrix are oriented anisotropically, such that thermal conduction in the electrically insulating carrier structure is effected anisotropically.

5. Device according to claim 4, wherein a first portion of the reinforcement fibres extends along a preferred direction, and a second portion of the reinforcement fibres extends along a second preferred direction, wherein the first preferred direction and the second preferred direction are arranged angularly to each other.

6. Device according to claim 5, wherein the first portion of the reinforcement fibres has a first ratio of a coating volume to the volume of the carrier structure 404 which first ratio differs from a second ratio of a coating volume of the second portion of the reinforcement fibres to the volume of the carrier structure.

7. Device according to claim 1, wherein at least one of the following is implemented:
i) the reinforcement structures comprise reinforcement grains,
ii) the reinforcement structures comprise hollow bodies,
iii) the reinforcement structures comprise glass or consist thereof.

8.-9. (canceled)

10. Device according to claim 1, comprising a separation structure which is arranged, for a spatial separation, between the coated reinforcement structures and the electrically conducting structure.

11. Device according to claim 1, wherein at least one of the following is implemented:
the coating is optically impermeable,
the coating has a thickness in a range between 300 nm and 10 μm.

12. (canceled)

13. Device according to claim 1, wherein the coating is a carbon coating comprising a mixture of sp² and sp³ hybridized carbon,
wherein the portion of sp² hybridized carbon is in a range between 30 and 65 percentage by weight, and the portion of sp³ hybridized carbon is in a range between 20 and 70 percentage by weight.

14. (canceled)

15. Device according to claim 1, wherein the reinforcement structures provided with the coating have a thermal conductivity in a range between 1 W/mK and 45 W/mK.

16. Device according to claim 1, wherein the reinforcement structures provided with the coating are jacketed with resin and the electrically conducting structure is arranged on and/or above the resin jacket, in order to thus separate the electrically conducting structure non-contactingly from the coating.

17. Device according to claim 1, wherein at least one of the following is implemented:
the electrically insulating carrier structure comprises prepreg material,
the carrier structure is a resinous board,
the electrically conducting structure comprises copper or consists thereof,
the device is formed as a printed circuit board.

18.-19. (canceled)

20. Device according to claim 1, comprising an electronic component (402), which is embedded in the carrier structure (102) and is coupled electrically conductingly with the electrically conducting structure,
wherein the electronic component is selected from a group that consists of an active electronic component and a passive electric component, as one from a group that consists of a filter, a voltage converter, a semiconductor chip, a storage module, a capacitor, an ohmic resistor, an inductor, a sensor and a high-frequency component.

21.-22. (canceled)

23. Device according to claim 1, wherein the carrier structure is formed of a plurality of layers that are arranged on top of each other, and wherein the device further comprises at least one further electronically conducting structure between the layers.

24. Method for manufacturing an electronic device, wherein the method comprises:
forming an at least partially electrically insulating carrier structure, which comprises a resin matrix and reinforcement structures in the resin matrix, wherein the reinforcement structures are provided at least partially with a thermal conductivity increasing coating;
forming an electrically conducting structure at and/or in the carrier structure;
wherein at least in an interconnecting section between the carrier structure and the electrically conducting structure, the carrier structure is kept free from reinforcement structures provided with the coating, such that the electrically conducting structure and the coating are arranged non-contactingly relative to each other.

25. Method according to claim 24, wherein the electrically insulating carrier structure is formed by providing the reinforcement structures WO individually with the thermal conductivity increasing coating, by cross-linking the coated reinforcement structures with each other, and by impregnating the reinforcement structures, which are coated and cross-linked with each other, with resin.

26. Method according to claim 24, wherein the electrically conducting carrier structure is formed by cross-linking the reinforcement structures with each other, by providing the cross-linked reinforcement structures jointly with the thermal conductivity increasing coating, and by impregnating the reinforcement structures, which are coated and cross-linked with each other, with resin.

27. Method according to claim 24, wherein the reinforcement structures are provided with the coating by sputtering or plasma-enhanced chemical vapour deposition.

28. Method according to claim 24, wherein a first portion of the reinforcement structures is aligned along a first extension direction, and a second portion of the reinforcement structures is aligned along a second extension direction, and wherein a distance between neighbouring reinforcement structures of the first portion is provided for differently from a distance between neighbouring reinforcement structures of the second portion.
